(19) United States
(12) Patent Application Publication
(10) Pub. No.: US 2014/0311713 A1
(43) Pub. Date: Oct. 23, 2014

(54) HEAT DISSIPATION COMPONENT

(71) Applicant: ASUSTEK COMPUTER INC., Taipei (TW)

(72) Inventors: Ming-Hsiu WU, TAIPEI (TW); Ta-Ching KUAN, TAIPEI (TW)

(73) Assignee: ASUSTEK COMPUTER INC., Taipei (TW)

(21) Appl. No.: 13/964,118

(22) Filed: Aug. 12, 2013

(30) Foreign Application Priority Data
Apr. 22, 2013 (CN) 201310140834.8

(51) Int. Cl. H05K 1/02

(52) U.S. Cl. CPC H05K 1/0209
USPC 165/104.32; 165/104.19

(57) ABSTRACT

A heat dissipation component includes a first film, a second film, and a working fluid. The second film is connected with a part of the first film to form a plurality of vein channels. The vein channels include a main vein channel and a plurality of branch vein channels, and the main vein channel is connected with the branch vein channels. The working fluid is disposed in the vein channels. The heat dissipation component is bendable to be easily assembled with an electronic device. The working fluid may flow in the vein channels via a pressure difference generated by a phase transition, gravity, and a capillary effect, or via a pressure difference generated, by a pulse generator to transfer the heat to the whole heat dissipation component. The first film and the second film may have heat conduction material to improve the heat transfer rate.

### CROSS-REFERENCE TO RELATED APPLICATION

This application claims the priority benefit of Chinese application serial No. 201310140834,8, filed on Apr. 22, 2013. The entirety of the above-mentioned patent application is hereby incorporated by reference herein and made a part of specification.

### BACKGROUND OF THE INVENTION

1. Field of the Invention

The invention relates to a heat dissipation component.

2. Description of the Related Art

A heat pipe or a heat plate used in a current consumer electronic product usually has a metal casing and working fluid. The working fluid, such as water, transfers heat via a circular gas-liquid phase transition in capillary structures of the casing to reduce temperature of electronic components contacted with the heat pipe or the heat plate.

Currently, a mobile device (such as a notebook computer, a tablet PC, or a telephone) becomes thinner and thinner, and thus an ultrathin heat pipe or an ultrathin heat plate is used therein. However, the heat pipe or the heat plate is usually difficult to be assembled in the mobile device because it is too thick, or the thickness of the whole mobile device cannot meet the requirement, which is rather inconvenience.

Furthermore, the heat pipe and the heat plate is rigid and cannot be bent, so they are not easily assembled or adhered to electronic components with irregular shapes. If the heat pipe or the heat plate is forced to bend, the capillary structures therein may be destroyed and the heat transfer effect may be reduced. In recent years, graphite flakes or other high heat conductive materials are used to overcome the above bending and adhering problems, but the coefficient of heat conduction of the graphite flakes or other high heat conductive materials (such as 200 to 1800 W/mK) is much less than the coefficient of heat conduction of the heat pipe or the heat plate such as 10000 to 50,000 W/mK). That is to say, the heat conductive efficiency and the space requirement are trade off in the mobile device with the conventional heat pipe or the heat plate.

### BRIEF SUMMARY OF THE INVENTION

A heat dissipation component includes a first film, a second film, and a working fluid. The second film is connected with a part of the first film to form a plurality of vein channels. The vein channels include a main vein channel and a plurality of branch vein channels, and the main vein channel is connected with the branch vein channels, respectively. The working fluid is accommodated in the vein channels.

### BRIEF DESCRIPTION OF THE DRAWINGS

FIG. 1 is a top view of a heat dissipation component according to a first embodiment;

FIG. 2 is a schematic diagram showing a cross-section of the heat dissipation component in FIG. 1 along a segment 2-2;

FIG. 3 is the heat dissipation component in FIG. 2 according to another embodiment;

FIG. 4 is a schematic diagram of the heat dissipation component in FIG. 1 assembled at a circuit board;

FIG. 5 is a top view of a heat dissipation component according to a second embodiment;

FIG. 6 is a schematic diagram showing a cross-section of the heat dissipation component in FIG. 5 along a segment 6-6;

FIG. 7 is a schematic diagram showing a cross-section of that a pulse generator in FIG. 6 presses the main vein channel;

FIG. 8 is a top view of a heat dissipation component according to a third embodiment;

FIG. 9 is a top view of a heat dissipation component according to a forth embodiment;

FIG. 10 is a top view of a heat dissipation component according to a fifth embodiment; and

FIG. 11 is a top view of a heat dissipation component according to a sixth embodiment.

### DETAILED DESCRIPTION OF THE EMBODIMENTS

These and other features, aspects and advantages of the present invention will become better understood with regard to the following description, appended claims, and accompanying drawings.

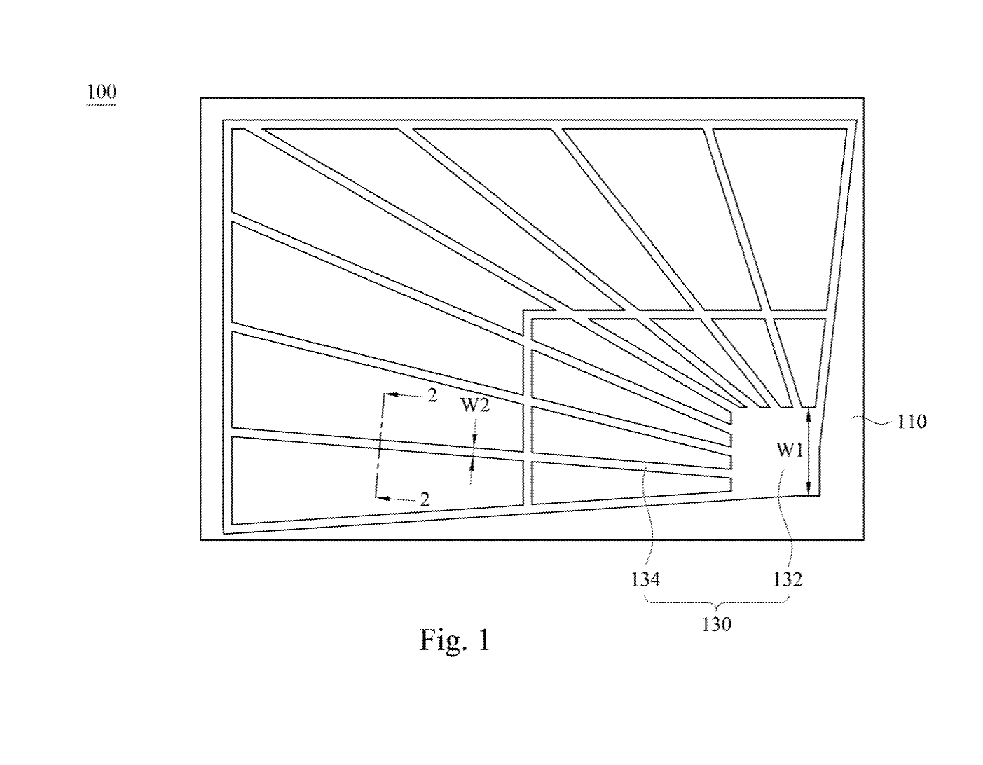

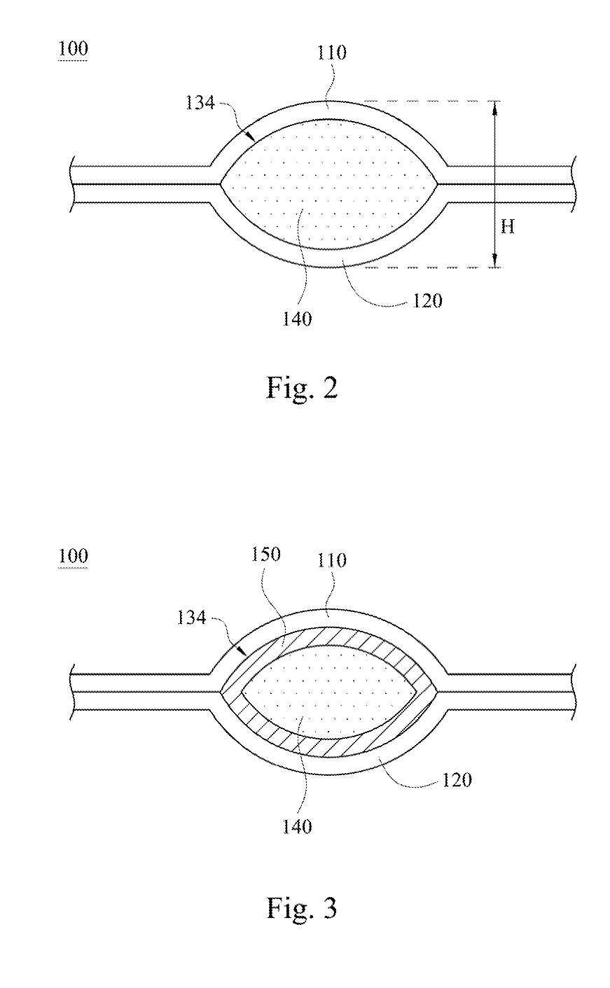

FIG. 1 is a top view of a heat dissipation component according to a first embodiment. FIG. 2 is a schematic diagram showing a cross-section of the heat dissipation component in FIG. 1 along a segment 2-2. Please refer to FIG. 1 and FIG. 2. The heat dissipation component 100 includes a first film 110, a second film 120, and a working fluid 140. The second film 120 is connected with a part of the first film 110 to form a plurality of vein channels 130.

The vein channels 130 are spaces between the first film 110 and the second film 120. The vein channels 130 include a main vein channel 132 and a plurality of branch vein channels 134, and the main vein channel 132 is connected with the branch vein channels 134. The vein channels 130 may protrudes from connecting locations between the first film 110 and the second film 120, and the working fluid 140 may be accommodated in the vein channels 130, which is not limited herein.

In the embodiment, the width W2 of the branch vein channels 134 is less than the width W1 of the main vein channel 132, In other embodiments, the width W2 of the branch vein channels 134 may be the same as the width W1 of the main vein channel 132, which is determined according to the demand of users.

In the embodiment, the first film 110 and the second film 120 may be metal films or nonmetal films coated by metal layers. For example, the metal film is an aluminum film, a copper film; the nonmetal film coated by metal layer is a plastic film (such as a PET film) coated by aluminum or a plastic film coated by copper. Both the metal film and the nonmetal film coated b metal layer have a characteristic of heat transmission.

The thickness H of the heat dissipation component 100 may be between 60 μm to 100 μm because the heat dissipation component 100 with this thickness is thin and bendable, but the range of the thickness is not limited the scope. Therefore, the heat dissipation component 100 also can be assembled to an electronic device or a housing with an irregular shape (such as a motherboard of a computer) or a regular shaped housing (such as an inner surface of a computer housing).

The working fluid 140 may be pure water, alcohol, acetone, or other volatile liquid, which is not limited herein. For example, when the working fluid 140 is methyl oxygen methane fluid, the boiling point is low and the volatility is high. When the main vein channel 132 of the heat dissipation component 100 is contacted with a heat source, the working fluid 140 of the main vein channel 132 may transfer the heat of the main vein channel 132 to the branch vein channels 134 via a pressure difference generated by a phase transition. The heat of the branch vein channels 134 also may be transferred to the whole heat dissipation component 100 via the first film 110 and the second film 120, so the temperature of the heat source may be effectively reduced. The connection location between the heat source and the heat dissipation component 100 is not limited at the main vein channel 132, for example, the heat dissipation component 100 also may be contacted with the branch vein channels 134. Furthermore, when the heat dissipation component 100 is used in a vertical direction (for example, the heat dissipation component 100 is attached to a side cover of a desktop computer), the working fluid 140 may flow in the vein channels 130 and transfer the heat under gravity.

In the embodiment, the branch vein channels 134 are radially arranged relative to the main vein channel 132, and the vein channels 130 are interlaced. The arrangement of the branch vein channels 134 and the main vein channel 132 in the first film 110 and the second film 120 is not used for limiting the scope.

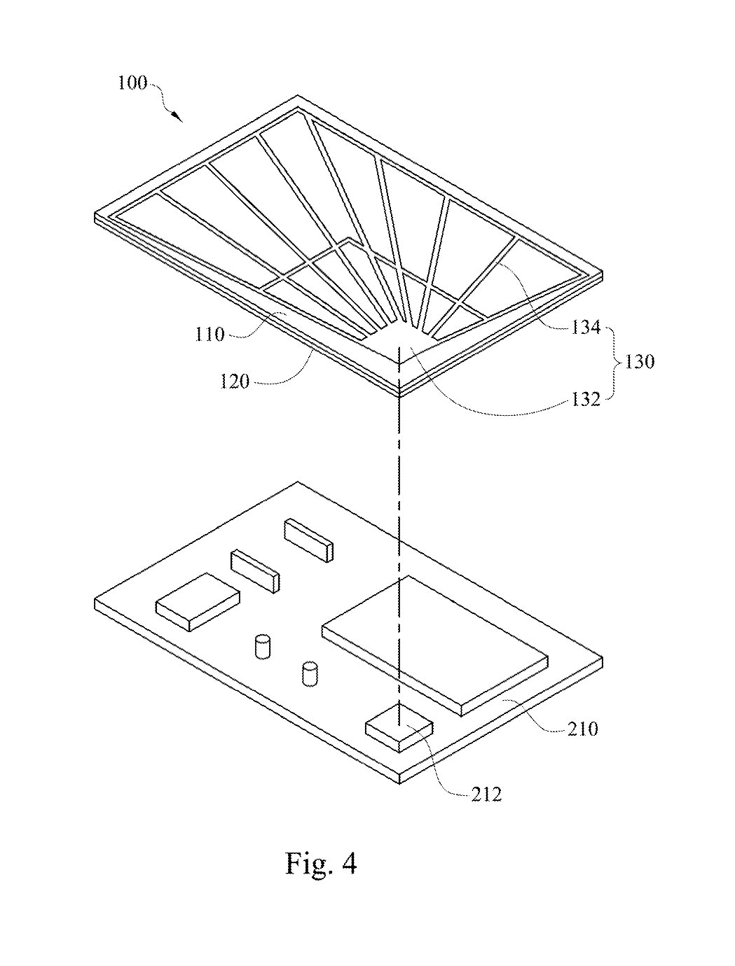

FIG. 3 is the heat dissipation component in FIG. 2 according to another embodiment. Compared with FIG. 2, the heat dissipation component 100 in FIG. 3 further includes a plurality of capillary structures 150, and the working fluid 140 therein may be water. Please refer to FIG. 1 and FIG. 3. The capillary structures 150 are disposed in the vein channels 130 (in the main vein channel 132 and the branch vein channels 134) and adhered to an inner surface of the vein channels 130. The capillary structures 150 may be metal sinters, micro grooves, or metal mashes. The vein channels 130 are evacuated, and the pressure therein is less than the atmospheric pressure, and thus the boiling point of the working fluid 140 is reduced (such as 50 to 70). In the embodiment, the working fluid 140 may flow in the vein channels 130 and transfer the heat via a pressure difference generated by a phase transition and a capillary effect. That is to say, when the main vein channel 132 is contacted with the heat source, the heat dissipation component 100 transfers the heat to the branch vein channels 134 according to a heat transferring principle of a heat pipe.

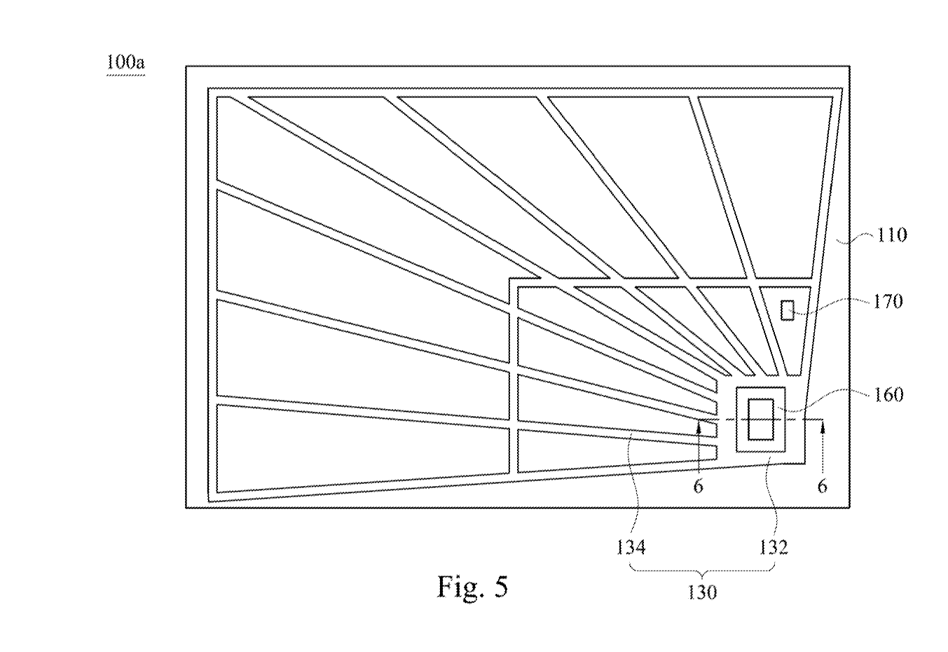

FIG. 4 is a schematic diagram of the heat dissipation component in FIG. 1 assembled at a circuit board. The circuit board 210 includes a heat source 212 and other minor heat sources (such as a capacitor or kinds of adapter card). The heat source 212 may be a central processing unit or a display chip. The heat dissipation component 100 is bendable, and thus it may contact with a plurality of electronic components of the circuit board 210. The working fluid 140 (refer to FIG. 2 and FIG. 3) may transfer the heat of the heat source 212 from the main vein channel 132 to the branch vein channels 134 via a pressure difference generated by a phase transition, gravity, and a capillary effect. Then, the heat of the branch vein channels 134 may also transfer to the whole heat dissipation component 100 via the first film 110 and the second film 120. Consequently, the temperature of the heat source 212 may be effectively reduced.

In the embodiment above, the heat dissipation component 100 is a passive heat dissipation component, that is to say, the working fluid 140 flows due to the heat of the heat source 212. Other type of the heat dissipation component will be described hereinafter.

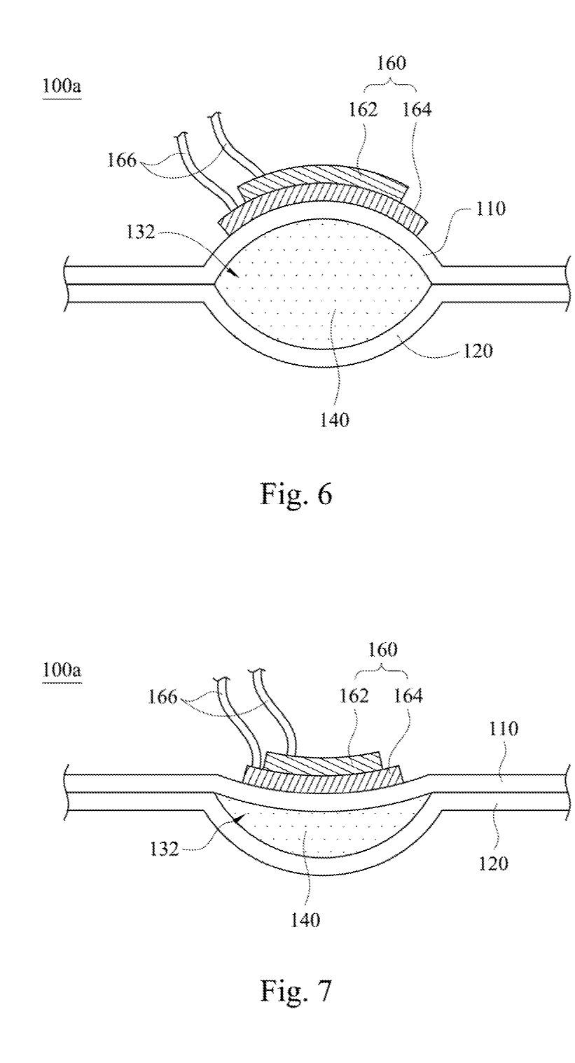

FIG. 5 is a top view of a heat dissipation component according to a second embodiment; FIG. 6 is a schematic diagram showing a cross-section of the heat dissipation component in FIG. 5 along a segment 6-6. Please refer to FIG. 5 and FIG. 6. A heat dissipation component 100a includes the first film 110, the second film 120, and working fluid 140. Compared with FIG. 1, the heat dissipation component 100a further includes a pulse generator 160 and a temperature control device 170, and the heat dissipation component 100a is a active heat dissipation component. The pulse generator 160 is disposed at the main vein channel 132 for applying pressure on the working fluid 140 in the main vein channel 132. The pulse generator 160 may include a ceramic piezoelectric material 162 and a piezoelectric metal material 164 (such as a Ni—Fe alloy). The temperature control device 170 is disposed on the first film 110 or the second film 120 and electrically connected with the pulse generator 160 via lead wires 166. The temperature control device 170 may control a bending degree of the piezoelectric material 164 to make the main vein channel 132 under the piezoelectric material 164 compressed or expanded.

FIG. 7 is a schematic diagram showing a cross-section of that a pulse generator in FIG. 6 presses the main vein channel. Please refer to FIG. 6 and FIG. 7. In the embodiment, the working fluid 140 is water and the vein channels 130 (as shown in FIG. 5 do not need to be evacuated. When the temperature control device 170 detects that a temperature is higher than a setting temperature (such as higher than 70), the temperature control device 170 enables the pulse generator 160 to change a bending direction of the pulse generator 160.

For example, the main vein channel 132 in FIG. 6 is in an expansion state, and the main vein channel 132 in FIG. 7 is in a compression state. When the heat source is contacted with the main vein channel 132 and the temperature increases, the pulse generator 160 is enabled by the temperature control device 170 to change the main vein channel 132 from the expansion state to the compression state. Then, the working fluid 140 in the main vein channel 132 may flow to the branch vein channels 134 (in FIG. 5), and the heat of the branch vein channels 134 may be transferred to the whole heat dissipation component 100a by the first film 110 and the second film 120, so the temperature of the heat source may be reduced by the water cooling effect.

When the main vein channel 132 is changed from the compression state to the expansion state, the working fluid 140 in the branch vein channels 134 (in FIG. 5) may flow back to the main vein channel 132 via the atmospheric pressure. The pulse generator 160 may periodically press the working fluid 140 in the main vein channel 132 to improve the heat dissipation efficiency of the heat dissipation component 100a.

Connection relationship described above is omitted herein for a concise purpose. The arrangement of the branch vein channels 134 and the main vein channel 132 on the first film 110 and the second film 120 is described hereinafter.

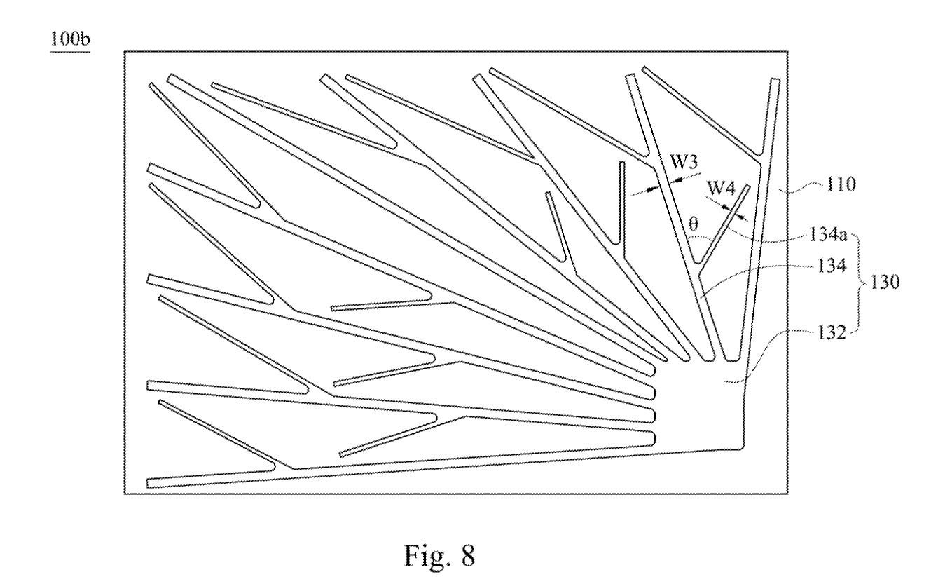

FIG. 8 is a top view of a heat dissipation component according to a third embodiment. Compared with FIG. 1, the vein channels 130 in FIG. 8 further include a plurality of lateral branch vein channels 134a. The main vein channel 132, the branch vein channels 134 and the lateral branch vein channels 134a are connected with each other to form arborescence channels. In the embodiment, the width W4 of the lateral branch vein channels 134a is less than the width W3 of the branch vein channels 134, and the angle between the lateral branch vein channels 134a and the branch vein channels 134 is between 5 to 85 degrees, which is not used for limiting, the invention. In other embodiments, the pulse generator 160 in FIG. 5 may be disposed at the main vein channel 132, which is not limited herein.

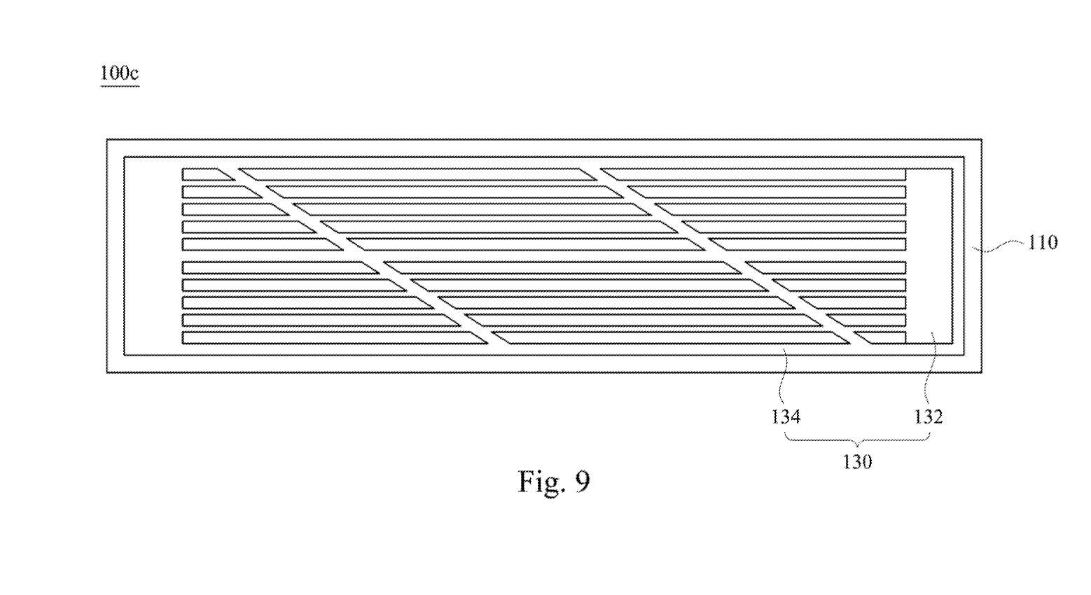

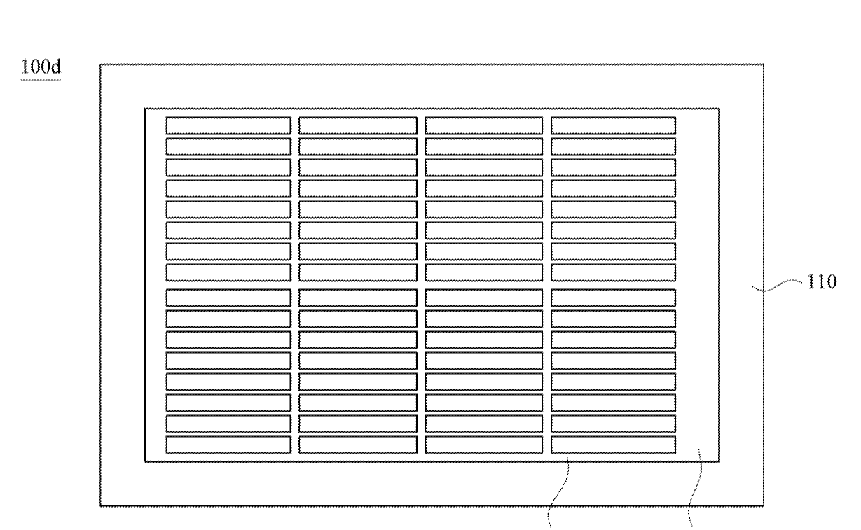

FIG. 9 is a top view of a heat dissipation component according to a forth embodiment. Compared with FIG. 1, the branch vein channels 134 in this embodiment are substantially parallel, and the main vein channel 132 is connected with the ends at the same side of the parallel branch vein channels 134. In other embodiments, the pulse generator 160 in FIG. 5 may be disposed on the main vein channel 132, which is not limited herein.

FIG. 10 is a top view of a heat dissipation component according to a fifth embodiment. Compared with FIG. 9, the heat dissipation component 100d in this embodiment has a larger area, parts of the branch vein channels 134 are arranged horizontally and another part of the branch vein channels 134 are arranged vertically, and thus the branch vein channels 134 are vertically connected with each other. Furthermore, the pulse generator 160 in FIG. 5 may be disposed on the main vein channel 132, which is determined according to the demand of users.

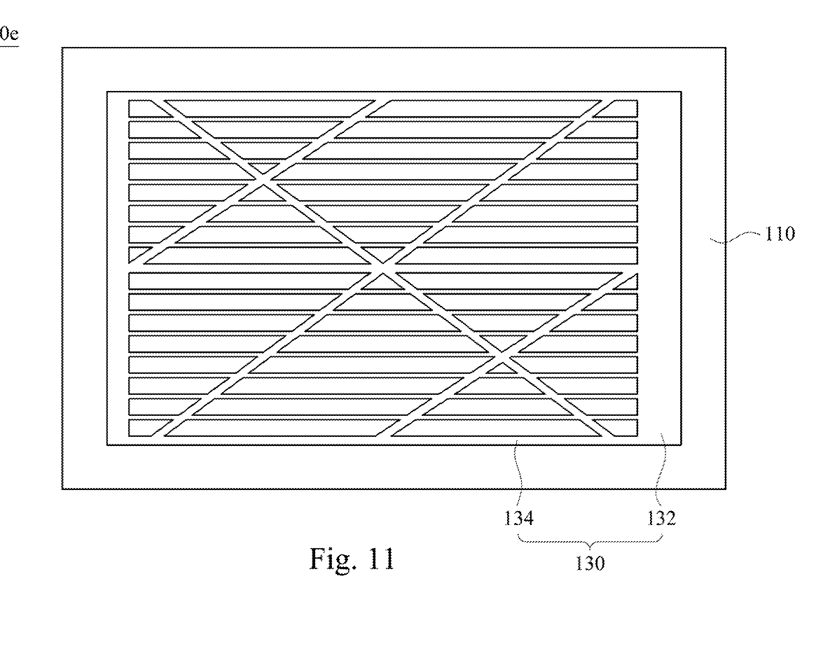

FIG. 11 is a top view of a heat dissipation component according to a sixth embodiment. Comparing with FIG. 10, the difference in this embodiment is that a part of the tilted branch vein channels 134 are interlaced with another part of the parallel branch vein channels 134. Furthermore, the pulse generator 160 in FIG. 5 may be disposed at the main vein channel 132, which is determined according to the demand of users.

Compared with conventional heat pipes or heat plates, the heat dissipation component in the embodiments includes a first film and a second film, and the heat dissipation component is bendable, and thus the heat dissipation component can be easily assembled or attached to the electronic device. The vein channels include the main vein channel and the branch vein channels, and the working fluid is accommodated in the vein channels, and thus the working fluid may flow in the vein channels via a pressure difference generated by a phase transition, gravity, and a capillary effect, or via a pressure difference generated by the pulse generator selectively to transfer the heat of the heat source to the whole heat dissipation component when the heat dissipation component is contacted with the heat source. Furthermore, the first film and the second film can dissipate heat due to the heat conducting characteristic of their material to improve the heat transfer rate.

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. A heat dissipation component comprising:
a first film;
a second film connected with a part of the first film to form a plurality of vein channels, wherein each the vein channel includes a main vein channel and a plurality of branch vein channels, and the main vein channel is connected with the branch vein channels, respectively; and
a working fluid accommodated in the vein channels.

2. The heat dissipation component according to claim 1, wherein the working fluid is pure water, alcohol, acetone, or other volatile liquids.

3. The heat dissipation component according to claim 1, further comprising:
a pulse generator disposed at the main vein channel for applying a pressure on the working fluid in the main vein channel.

4. The heat dissipation component according to claim 1, wherein the branch vein channels are radially arranged relative to the main vein channel.

5. The heat dissipation component according to claim 3, further comprising:
a temperature control device disposed on the first film or the second film and electrically connected with the pulse generator.

6. The heat dissipation component according to claim 1, wherein the branch vein channels are parallel.

7. The heat dissipation component according to claim 1, wherein the branch vein channels are interlaced.

8. The heat dissipation component according to claim 1, wherein the width of the branch vein channels is the same as the width of the main vein channel.

9. The heat dissipation component according to claim 1, wherein the width of the branch vein channels is less than the width of the main vein channel.

10. The heat dissipation component according to claim 1, further comprising:
a plurality of capillary structures disposed in the vein channels and attached to an inner surface of the vein channels.

11. The heat dissipation component according to claim 1, wherein the first film and the second film are metal films or nonmetal films coated by metal layers.
